(19) United States
(12) Patent Application Publication
(10) Pub. No.: US 2005/0219475 A1
(43) Pub. Date: Oct. 6, 2005

(54) Illumination device integrated into a projection type display, and projection type projector

(75) Inventor: Hisayuki Mihara, Saitama (JP)

Correspondence Address: PILLSBURY WINTHROP SHAW PITTMAN, LLP, P.O. BOX 10500, MCLEAN, VA, 22102, US

(73) Assignee: KABUSHIKI KAISHA TOSHIBA, Tokyo (JP)

(21) Appl. No.: 11/094,492

(22) Filed: Mar. 31, 2005

(30) Foreign Application Priority Data
Mar. 31, 2004 (JP) 2004/108114

(51) Int. Cl. H01L 29/18

(52) U.S. Cl. 353/94

(57) ABSTRACT

An illumination device integrated into a projection type display, and projection type projector include a combination prism for combining RGB light emitted from RGB LED light sources and causing the combined light to be emitted to a single-plate light valve, wherein the emission of the LED light sources is controlled in response to the PWM drive control of the single-plate light valve. An incident angle (emitted angle) θ2 and an incident (emitting) size d2 are set to the following relation through kaleidoscopes with respect to the divergent angle θ1 and the diverging size d1 of the LED light sources.
d1·sin θ1=d2·sin θ2

### CROSS-REFERENCE TO RELATED APPLICATIONS

This application is based upon and claims the benefit of priority from the prior Japanese Patent Application No. 2004-108114 filed on Mar. 31, 2004; the entire contents of which are incorporated herein by reference.

### BACKGROUND OF THE INVENTION

1. Field of the Invention

The present invention relates to an illumination device integrated into a projection type display using an LED (light emitting diode) as a light source and being capable of obtaining illumination light in synchronism with the drive of a single-plate light valve and relates to a projection type projector.

2. Description of Related Art

Heretofore, discharge lamps such as a mercury lamp, a metal halide lamp, a xenon lamp, and the like are used as an illumination light source for a projection type display. When these discharge lamps are used in a projection type display using a three-plate liquid crystal panel, only light of a polarized component passing through the liquid crystal panel is used, a problem arises in that the brightness of the light is attenuated.

Further, a projection type display, which displays a color video picture by a single-plate light valve represented by, for example, a DMD (digital micromirror device) using a white light source, employs an illumination device and a projection type projector. In the illumination device and the projection type projector, color wheels (hereinafter, abbreviated as CWs) having red, green, and blue (hereinafter, abbreviated as RGB) disc shaped color filters (wavelength limited), which are disposed within an arbitrary angle range, are rotated in synchronism with picture signals, and a color video picture is displayed by guiding the light sequentially passed through the respective RGB filters disposed in the CWs to a projection lens via light valves driven in response to the picture signals.

In contrast, recently, semiconductor light sources such as a semiconductor laser, an LED, and the like are used as a light source of projection type projectors because the light emission efficiency and the emitted amount of light of the semiconductor light sources are greatly improved and developed. For example, Japanese Unexamined Patent Application Publication No. 2002-72358 discloses a technology for displaying a color video picture by creating laser beams having respective RGB wavelengths by subjecting laser beams from semiconductor lasers to convert upward, projecting the RGB laser beams to RGB light valves using kaleidoscopes, combining the transmitted light from the respective light valves by a combination prism, and guiding it to a projection lens.

A conventional pulse width modulation (PWM) method controls light intensity by executing integration with respect to time by rotating a CW having RGB filters in synchronism with picture signals, when white light emitted from a discharge lamp as well as a single-plate light valve is used as a light source, and turns on a DMD element as a single-plate light valve according to picture luminance information with respect to the RGB light passed through the color filters of the CW. In this method, when any single RGB color is displayed, other color components are discarded, thus light utilization efficiency is deteriorated.

A three-plate light valve, which corresponds to RGB primary colors respectively, must be used to improve the light utilization efficiency. However, three sheets of the expensive light valves being used, not only cost is increased but also an optical system is necessary to separate and combine RGB light, from which a problem arises in that the size of a projection type projector is increased.

When a single-plate light valve is used when using white light emitted from an LED as a light source, a disadvantage similar to that of the discharge lamp occurs. Further, because it is expensive, it is not practical to use the three-plate light valve except that a relatively inexpensive liquid crystal light valve is employed.

When the liquid crystal light valve is used, since only light having a particular polarized light component is used, the other polarized light components are discarded. Otherwise, there is required a system for separating random polarized light to two polarized light components orthogonal to each other, rotating the direction of one of the polarized light components at 90°, and combining the polarized light components again. The system, which separates the random polarized light to the two orthogonal polarized light components, rotates one of the polarized light component at 90°, and combines them, is equivalent to the state in which a light source area provided with it is only one half that of the light valve system which can construct a light valve in a random polarized light state. Accordingly, the system has a problem in that a desired amount of light cannot be obtained even if the light emission efficiency of LED is improved.

That is, when the area of a light valve shown by S1 and an illumination solid angle shown by NA1 are determined, a light emission area S2 of an LED having a large light emission solid angle has the following relation when a light emission solid angle is shown by NA2.
S1·NA1=S2·NA2
Accordingly, the light emission area of the LED is within the range of S2=S1·NA1/NA2. As it is obvious from the expression, even if the LED is disposed in an area larger than the light emission area S2 provided therewith, it is impossible in principle for the LED to execute illumination at an illumination angle within the illumination solid angle NA1 including a projection lens in the effective area S1 of the light valve.

Therefore, when a single-plate light valve, which has the same size as the three-plate light valve provided to light valves for respective RGB, is used, an area of a light source is ⅓ in a simple calculation, from which a disadvantage arises in that an amount of light only one third that of the three-plate light valve is obtained in the single-plate light valve.

In contrast, the disadvantage described above can be avoided in a laser light source having a minimum light source area. However, an expensive light source system including a cooling unit is necessary to guide laser beams and, in addition, when a laser beam in short wave represented by blue is used, afterglow remains for an arbitrary time due to a laser beam creation method particularly employing an upward conversion system. Accordingly, a problem arises in that it is not suitable to use the laser light source to the single-plate light valve to which a high shut-off speed is required to secure high quality.

In view of the above circumstances, an object of the present invention is to provide an illumination device integrated into a projection type display capable of controlling lighting at a high speed in synchronism with a single-plate light valve, and to provide a projection type projector.

### BRIEF SUMMARY OF THE INVENTION

To achieve the above object, an illumination device integrated into a projection type display of the present invention includes a light combination unit which combines red light, green light, and blue light emitted from red (R), green (G), blue (B) LED light sources and causing the combined light to be emitted to a single-plate light valve, a light valve drive unit which drives and controls the single-plate light valve in response to picture signals, and an LED light source control unit which controls the emission of the LED light sources in synchronism with the single-plate light valve driven by the light valve drive unit.

Further, a projection type projector includes a light combination section which combines red light, green light, and blue light emitted from red (R), green (G), blue (B) LED light sources and causing the combined light to be emitted to single-plate light valve, a light valve drive section which drives and controls the single-plate light valve in response to picture signals, and an LED light source control section which controls the emission of the LED light sources in synchronism with the single-plate light valve driven by the light valve drive section.

According to these arrangements, the LED light sources can be driven very effectively with a high output and a high speed response without reducing the life thereof, thereby a very bright projected image of high quality can be obtained even if the single-plate light valve is used.

### BRIEF DESCRIPTION OF THE DRAWINGS

FIG. 1 is a block diagram showing an arrangement of an illumination device integrated into a projection type display according to a first embodiment of the present invention;

FIG. 2 is a block diagram showing an arrangement of an illumination device integrated into a projection type display according to a second embodiment of the present invention;

FIG. 3 is a view explaining a problem of a color wheel used in an illumination device integrated into a conventional projection type display; and

FIG. 4 is a time chart explaining the actions of the illumination device integrated into a projection type display according to the present invention and the conventional illumination device.

### DETAILED DESCRIPTION OF THE INVENTION

Embodiments of the present invention will be explained below in detail with reference to the drawings. An illumination device integrated into a projection type display of the present invention has been invented by paying attention to that an LED light source can be not only pulse driven with its property but also driven by being supplied with three times of usual drive power in one-third time with its structure. In addition, a bandwidth is not necessary to increase by transforming a polarized light component even if a combination prism is used because the wavelengths of emitted light are not continuous among RGB colors, and thus a less expensive and highly effective illumination device, which can follow up an operation for switching light source colors of light valves, can be constructed.

### First Embodiment

FIG. 1 shows an arrangement of an illumination device integrated into a projection type display according to a first embodiment of the present invention.

Light from RGB LED light sources 11R, 11G, and 11B, which constitute three primary colors of light, is guided to a combination prism 13 through kaleidoscopes 12R, 12G, and 12B provided respectively with the LED light sources 11R, 11G, and 11B and combined to white light by the combination prism 13.

The RGB LED light sources 11R, 11G, and 11B are disposed at one ends of the kaleidoscopes 12R, 12G, and 12B. Open ends of the kaleidoscopes 12R, 12G, and 12B are disposed to the light incident surfaces of the regular cubic combination prism 13 formed on side surfaces thereof. The combination prism 13 combines the RGB light incident from the light incident surfaces and causes white combined light 14 to be emitted from a light emitting surface. The kaleidoscope 12 has an inner periphery which is located between one end thereof where the LED 11 is disposed and the opening end thereof located on the light incident surface of the combination prism 13 and is surrounded by, for example, a mirror.

When the effective light divergent angle of the LED light source 11 is shown by θ1, the light diverging size of the LED light source 11 is shown by d1, the size (=opening size of the kaleidoscope 12) of light incident to the combination prism 13 is shown by d2, and the angle of incident to the combination prism 13 (=light emitted angle from the combination prism 13) is shown by θ2 as shown in FIG. 1, the combination prism 13 is set to a prism condition satisfying the relation shown by the following equation.
d1·sin θ1=d2·sin θ2

When, for example, a discharge lamp is used as a light source of the combination prism 13, since the light source wavelength from the discharge lamp is continuous, combination efficiency must be secured by orthogonalizing the polarizing axis of green (G) incident light to the polarizing axes of red (R) and blue (B) incident light as described above. However, when the LED light source 11 is used, since no emission spectrum exists among RGB colors in many cases, the polarization axis transformation is not necessary unless a wavelength near those of RGB is selected.

That is, the RGB light from the RGB LED light sources 11R, 11G, and 11B is guided to the combination prism 13 through the kaleidoscopes 12R, 12G, and 12B, is combined by the combination prism 13, and is caused to be emitted as combined light 14 having the divergent angle θ2 according to the shape and the size of the combination prism 13.

To satisfy the condition of the divergent angle θ2 of the combined light 14 achieved by the combination prism 13, the length L of the RGB kaleidoscopes 12R, 12G, and 12B is determined to satisfy the relation between a maximum direct incident angle θ0 and the combined divergent angle θ2, the relation to be such that the straight line 15 in FIG. 1 that connects an end of the LED light source 11 to the opening end of the kaleidoscope 12 in the diagonal direction from the end, that is, the angle θ0 of the maximum direct incident light, which is emitted from the LED light source 11 and is directly incident on the opening end of the kaleidoscope 12 without reflecting thereby even only once, does not exceed the θ2 which is the divergent angle condition of the combined light 14 emitted from the combination prism 13.

Note that when a light path length loss occurs in the combination prism 13, an arbitrary relay lens 16 may be provided to cancel the light path length loss.

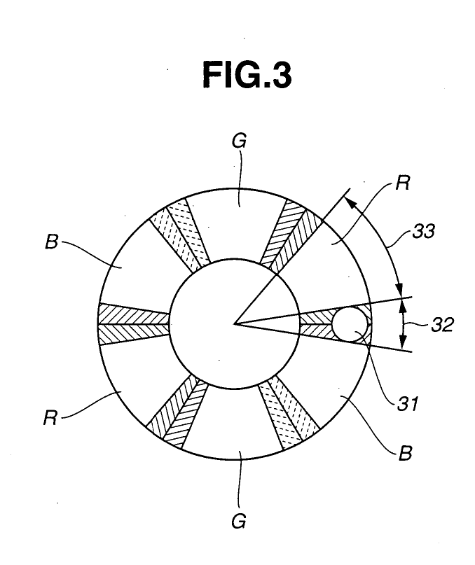

The combined light 14 created by the illumination device arranged as described above can be captured as white light having a predetermined divergent angle θ2. Accordingly, when, for example, single-plate light valves are used, an illumination device integrated into a projection type display having a performance similar to a conventional performance can be constructed by using color wheels (CWs) having RGB filters shown in FIG. 3.

However, the following disadvantages arises upon using the CWs, in addition to the efficiency problem when arbitrary one of the RGB colors is selected as described above. A first disadvantage arises when a time-division color switching is performed. This disadvantage is so-called “color breaking” or “rainbow noise” in which a video picture is recognized in each simple RGB color because an increase in control speed of the CWs reaches a limit with respect to a DMD element that is driven in response to a switching frequency of the RGB colors displayed by driving and controlling the DMD element in time division and thus a displayed color is not sufficiently integrated by human eyes.

A second disadvantage arises due to mixed color light when a color is switched by the CW. As shown in FIG. 3, the CW inevitably includes a boundary range 32 of an arbitrary color of RGB and other color of the boundary in each of RGB boundaries, from which a mixed color portion 31 is created. The boundary range 32 cannot be driven as a RGB simple color. It is possible to cause all the boundary ranges 32 of the CW to contribute as the luminance of a black/white video picture. However, the mixed color portions 31 of the boundary ranges 32 have an arbitrary deviation according to light sources because the conditions of the RGB light source ratios of them are not always uniform, from which a disadvantage arises in that white light whose quality is deteriorated is multiplexed.

As a result, since a pure color range 33 allocated to each RGB color is narrowed, gradations cannot be sufficiently displayed, from which a disadvantage arises in that quantized noise is generated in a dark portion.

In contrast, the LED light sources 11R, 11G, and 11B used in the illumination device of the present invention has such high speed responsiveness that the LED light source can be utilized in communication. By making use of the high speed responsiveness of the LED light source 11, the LED light source 11 is driven optimally by being synchronized with the drive of a single-plate light valve capable of sufficiently displaying gradations.

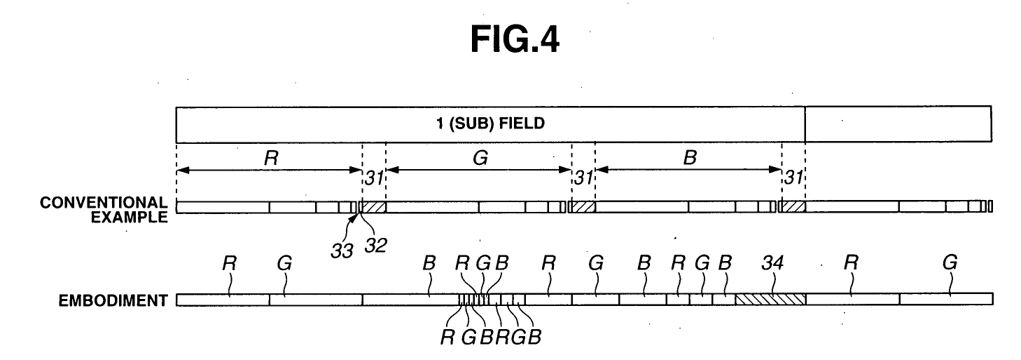

The optimum drive operation of the single-plate light valve and the LED light source 11 will be explained with reference to a time chart shown in FIG. 4. Note that FIG. 4 shows a conventional example using a CW and the illumination device according to the first embodiment by contrasting them with each other.

One subfield generally corresponds to one frame and is set to about two times in a business model and to about 4 to 5 times in a home theater model mainly used for moving pictures. Respective subfields are further divided into RGB subfields according to the CW that is driven in rotation in synchronism with the operation of the single-plate light valve. The light valve is turned on during a display time weighted by a video picture level within the illumination time of the RGB colors, thereby the light reflected from the light valve is guided to a projection lens.

In the illumination device using the CW of the conventional example, a PWM modeling for obtaining simple 256 gradations by equally dividing RGB is shown to simplify explanation of the drive using video picture digital data. As in the conventional example, the mixed color portion 31 of the CW shown in FIG. 3 described above is discarded to drive white color or to secure a color rendering capability.

Further, there is a case that a lightening time shorter than the drive period (address period) of the single-plate light valve in lower bits shown by reference numeral 32 in the figure is required to reduce the color breaking in the home theater model in which a color is switched at a high speed. Accordingly, a PWM loss caused by a drive rate is at a level beyond negligence as shown by reference numeral 33 in the figure.

In contrast, since the LED light source 11 of the illumination device according to the first embodiment has the high speed responsiveness as described above, it can be driven in synchronism with the DMD element that is driven at high speed in response to PWM of 256 gradations. It is possible, for example, that after red light is emitted from the R LED light source 11R and the most significant bit of the red light (R) is displayed, green light (G) is emitted from the G LED light source 11G and the most significant bit is switched to an arbitrary bit of the green light (G). As described above, the number of the subfields can be reduced by sequentially executing switching to an arbitrary bit of an arbitrary color, thereby the PWM loss 33 can be reduced. Accordingly, when the number of the subfields is not reduced, quality resulting from switching of colors can be visually improved.

Further, since the life of the LED light source 11 is not adversely affected even if it is supplied with three times of usual drive power in one-third time as described above, it can be expected to increase the amount of emitted light by controlling light emission each bit.

Note that the quantized noise described above can be also reduced by switching the lighting drive of the LED light source 11, which cuts the amount of light itself of the LED light source 11 into half when the maximum value accumulated in a frame memory goes down to below 50% of the maximum allowable amount of the frame memory, as well as by shifting the drive signal of the DMD element of the single-plate light valve by 1 bit.

Further, in the illumination device of the first embodiment, since no CW is used, the mixed color portion 31 does not exist in principle. It is also possible that a period corresponding to the mixed color portion 31 denoted by reference numeral 34 shown in the figure is portioned to the gradation display period of each RGB color. A projection type display, from which a projected video picture of higher quality can be obtained without sacrificing brightness, can be realized by using the gradation display period to the detailed bit gradation display of green (G) in which quantized noise is noticeable particularly in the dark portion.

### Second Embodiment

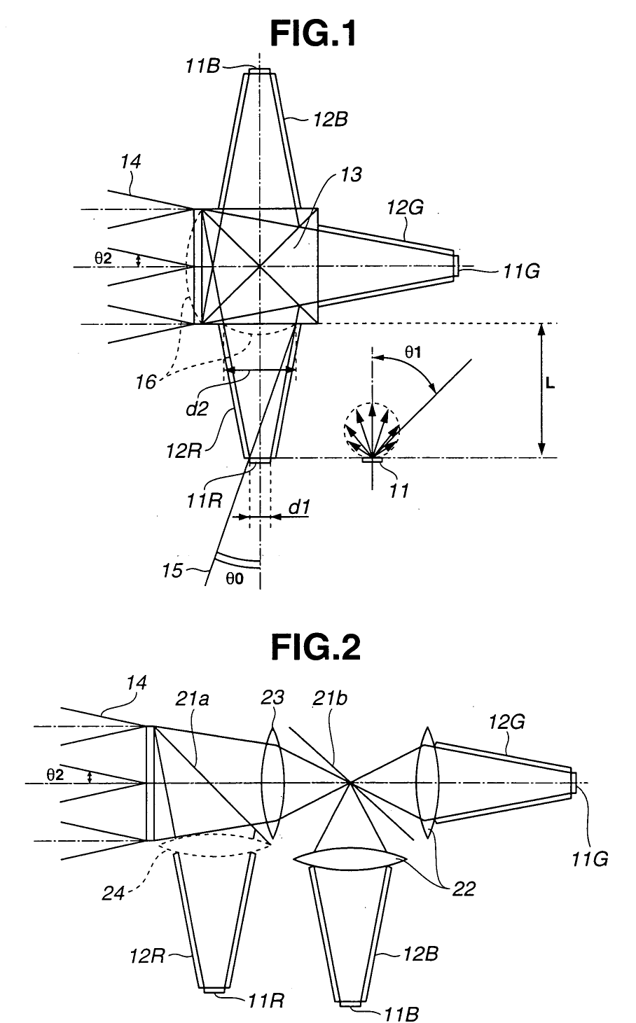

FIG. 2 shows an illumination device integrated into a projection type display according to a second embodiment of the present invention. The illumination device integrated into the projection type display shown in FIG. 1 combines the light from the RGB LED light sources 11R, 11G, and 11B using the combination prism 13. In the illumination device integrated into the projection type display according to the second embodiment uses a dichroic mirror 21 in place of the combination prism 13. Note that the same components as those shown in FIG. 1 are denoted by the same reference numerals, and the detailed description thereof is omitted.

In the illumination device according to the second embodiment, R light emitted from an opening end of a kaleidoscope 12R having an R LED light source 11R is incident on a first dichroic mirror 21a, G light emitted from an opening end of a kaleidoscope 12G having a G LED light source 11G is incident on a second dichroic mirror 21b, and B light emitted from an opening end of a kaleidoscope 12B having a B LED light source 11B is incident on the second dichroic mirror 21b. The first dichroic mirror 21a reflects the R light and transmits the G light and the B light. The second dichroic mirror 21b transmits the G light and reflects the B light.

That is, the transmitted G light from the G LED light source 11G is combined with the reflected B light from the B LED light source 11B by the second dichroic mirror 21b and is output to the first dichroic mirror 21a. The first dichroic mirror 21a combines the combined G and B light with the R light from the R LED light source 11R and emits resultant white light.

The same operation and action as those of the first embodiment can be obtained by the above arrangement. Note that since RGB light path lengths are different from each other by using the first and second dichroic mirrors 21a and 21b, relay lenses 22, 23, and 24 may be used when necessary.

1. An illumination device integrated into a projection type display comprising:
a light combination unit which combines red light, green light, and blue light emitted from red (R), green (G), blue (B) LED light sources and causing the combined light to be emitted to a single-plate light valve;
a light valve drive unit which drives and controls the single-plate light valve in response to picture signals; and
an LED light source control unit which controls the emission of the LED light sources in synchronism with the single-plate light valve driven by the light valve drive unit.

2. A projection type projector comprising:
a light combination section which combines red light, green light, and blue light emitted from red (R), green (G), blue (B) LED light sources and causing the combined light to be emitted a single-plate light valve;
a light valve drive section which drives and controls the single-plate light valve in response to picture signals; and
an LED light source control section which controls the emission of the LED light sources in synchronism with the single-plate light valve driven by the light valve drive section.

3. The illumination device integrated into a projection type display according to claim 1, wherein the light valve drive unit drives and controls the single-plate light valve in response to a pulse width modulation of the subfield unit of picture signals.

4. The illumination device integrated into a projection type display according to claim 1, wherein the light valve drive unit drives and controls the single-plate light valve each bit showing the RGB gradations of picture signals.

5. The illumination device integrated into a projection type display according to claim 1, wherein the light combination unit comprises:
kaleidoscopes for guiding the red light, the green light, and the blue light emitted from the LED light sources; and
a combination prism having incident surfaces formed on openings of the kaleidoscopes to combine and emit the red light, the green light, and the blue light guided by the kaleidoscopes.

6. The illumination device integrated into a projection type display according to claim 1, wherein the light combination unit comprises:
kaleidoscopes for guiding the red light, the green light, and the blue light emitted from the LED light sources; and
dichroic mirrors for combining the red light, the green light, and the blue light emitted from openings of the kaleidoscopes.

7. The illumination device integrated into a projection type display according to claim 5, wherein the length of each of the kaleidoscopes is set within such a range that the maximum direct incident angle between the optical axis center of each of the LED light sources and the straight line that connects an end of each LED light source to an opening end of each kaleidoscope in the diagonal direction from the end of each LED light source does not exceed the incident angle from the opening end of each kaleidoscope to the combination prism or each dichroic mirror.

8. The illumination device integrated into a projection type display according to claim 6, wherein the length of each of the kaleidoscopes is set within such a range that the maximum direct incident angle between the optical axis center of each of the LED light sources and the straight line that connects an end of each LED light source to an opening end of each kaleidoscope in the diagonal direction from the end of each LED light source does not exceed the incident angle from the opening end of each kaleidoscope to the combination prism or each dichroic mirror.

9. The projection type projector according to claim 2, wherein the light valve drive section drives and controls the single-plate light valve in response to a pulse width modulation of the subfield unit of picture signals.

10. The projection type projector according to claim 2, wherein the light valve drive section drives and controls the single-plate light valve each bit showing the RGB gradations of picture signals.

11. The projection type projector according to claim 2, wherein the light combination section comprises:
kaleidoscopes for guiding the red light, the green light, and the blue light emitted from the LED light sources; and
a combination prism having incident surfaces formed on openings of the kaleidoscopes to combine and emit the red light, the green light, and the blue light guided by the kaleidoscopes.

12. The projection type projector according to claim 2, wherein the light combination section comprises:
kaleidoscopes for guiding the red right, the green light, and the blue light emitted from the LED light sources; and
dichroic mirrors for combining the red light, the green light, and the blue light emitted from openings of the kaleidoscopes.

13. The projection type projector according to claim 11, wherein the light combination section sets an incident angle (emitted angle) θ2 and an incident (emitting) size d2 to a combination prism or to each dichroic mirror to the following relation through each kaleidoscope with respect to the light divergent angle θ1 and the diverging size d1 of light emitted from each LED light source.
d1·sin θ1=d2·sin θ2

14. The projection type projector according to claim 12, wherein the light combination section sets an incident angle (emitted angle) θ2 and an incident (emitting) size d2 to a combination prism or to each dichroic mirror to the following relation through each kaleidoscope with respect to the light divergent angle θ1 and the diverging size d1 of light emitted from each LED light source.
d1·sin θ1=d2·sin θ2

15. The projection type projector according to claim 11, wherein the length of each of the kaleidoscopes is set within such a range that the maximum direct incident angle between the optical axis center of each of the LED light sources and the straight line that connects an end of each LED light source to an opening end of each kaleidoscope in the diagonal direction from the end of each LED light source does not exceed the incident angle from the opening end of each kaleidoscope to the combination prism or each dichroic mirror.

16. The projection type projector according to claim 12, wherein the length of each of the kaleidoscopes is set within such a range that the maximum direct incident angle between the optical axis center of each of the LED light sources and the straight line that connects an end of each LED light source to an opening end of each kaleidoscope in the diagonal direction from the end of each LED light source does not exceed the incident angle from the opening end of each kaleidoscope to the combination prism or each dichroic mirror.

17. The projection type projector according to claim 13, wherein the length of each of the kaleidoscopes is set within such a range that the maximum direct incident angle between the optical axis center of each of the LED light sources and the straight line that connects an end of each LED light source to an opening end of each kaleidoscope in the diagonal direction from the end of each LED light source does not exceed the incident angle from the opening end of each kaleidoscope to the combination prism or each dichroic mirror.
